(19) United States
(12) Patent Application Publication
(10) Pub. No.: US 2015/0373869 A1
(43) Pub. Date: Dec. 24, 2015

(54) Housing for Electronic Power Components and a Power Converting Device

(71) Applicant: ABB TECHNOLOGY AG, Zürich (CH)

(72) Inventors: Sauro Macerini, Levane-Montevarchi (AR) (IT); Andrea Becattini, Cavriglia (AR) (IT); Francesco Del Francia, Firenze (IT)

(21) Appl. No.: 14/766,387

(22) PCT Filed: Feb. 11, 2013
(86) PCT No.: PCT/IT2013/000042

§ 371 Date: Aug. 6, 2015

(51) Int. Cl. H05K 7/20; H05K 5/02; H05K 5/03

(52) U.S. Cl. CPC H05K 7/209; H05K 7/2089; H05K 5/03; H05K 5/0213

(57) ABSTRACT

A housing for electronic power components, comprising a compartment (13) and a front cover (14) for closing the compartment (13). An insulating air space (18) is defined on the cover (14).

### TECHNICAL FIELD

The present invention relates to the field of electronic power components, in particular in systems for producing electrical current. More in detail, the invention relates to a housing for electronic power components and to a device for converting electrical current from direct to alternating in photovoltaic systems comprising said housing.

### STATE OF THE ART

Currently, in the majority of photovoltaic systems, devices are used to convert direct electrical current, produced in the photovoltaic generation module, into alternating electrical current to be fed into the distribution network.

These devices are formed by a housing containing an inverter and the electronic components required for the operation thereof.

The housing is produced by a box-shaped container provided with a front part equipped with an opening for access to the compartment of the housing and a back part for fastening to a supporting structure.

Two elements are associated with the front part, a first element formed by a cover that reversibly closes part of the opening for access to the compartment and a second element formed by a heat dissipation module having outwardly projecting dissipating fins. The inner portion of the heat dissipation module is in thermal contact with the inverter, so as to dissipate the large quantity of heat generated thereby during operation. The dissipation module is provided with an outer mask having purely aesthetic functions.

The dissipating properties of the conversion devices in photovoltaic systems are fundamental for optimal operation thereof, in particular in periods of maximum exposure to the sun, for example in summer. In fact, in this period the operating temperatures are very high.

To attempt to reduce the temperatures, it would be advisable to position the devices in shady areas. However, it is evident that this option is very often impractical, given that the photovoltaic system must, by definition, be exposed to the greatest possible amount of sunlight and therefore positioned far from shaded areas.

The heat deriving from operation of the device together with the heat radiated directly from the sun onto the device cause the electronics of this latter to operate in critical temperature conditions, i.e. temperatures that are not optimal, both with regard to reliability and to overall performance.

### OBJECT AND SUMMARY OF THE INVENTION

The main object of the present invention is to reduce the operating temperature in electronic devices exposed to sunlight by designing a housing for electronic power components, particularly but not exclusively for devices for converting electrical current from direct to alternating as described above, which allows the effect of heating caused by the sun's rays to be reduced.

Within the aforesaid main object, another important object of the present invention is to produce a housing for electronic power components, and a conversion device using said housing, which allows installation and maintenance operations to be facilitated.

These and other objects, which will be more apparent below, are achieved, according to a first aspect of the invention, with a housing for electronic power components, comprising a compartment and a front cover for closing the compartment; an air space is defined on the cover, so that the air in the air space contributes to the thermal insulation of the cover and therefore of the compartment.

According to some particularly advantageous embodiments, the cover also comprises a thermal radiation barrier. Preferably, this thermal radiation barrier comprises a heat reflecting film or panel. Preferably, the barrier is arranged in the air space.

According to some preferred embodiments, the air space is provided with openings toward the outside environment to allow ventilation of the air space. In practice, the cover of the housing is a ventilating cover and therefore allows, through the effect of ventilation, cooling of the cover relative to the heat collected by the outer surface radiated by the sun, thereby limiting the transfer of heat from the outside toward the inside of the housing and consequently allowing improved performance of the device and increased reliability of its electronic components.

Conveniently, according to a preferred embodiment of the invention, the front part of the air space interfacing with the outside environment comprises insulating means, which can be arranged in addition to, integrated in, or to coincide with, the thermal radiation barrier. The presence of these means allows much of the heat coming from the outside to be confined on this interface, limiting the heat that passes through the air space and that, in any case, is dissipated by the ventilating effect thereof.

Advantageously, the insulating means comprise a film or panel made of heat insulating material, preferably in contact with the inner face of the front part of the air space. This allows optimization of the insulating effect, without compromising the protective features of this front part, which acts as a barrier in the case of slight impacts. Film or insulating panel and film or heat reflecting panel can be integrated in a single film or panel.

The reflecting and/or insulating material is, for example, an expanded polymeric material, such as a material based on low density polyethylene foam, for example the material known with the trade name Plastazote LD24 FR, while the front part, i.e. the interface with the outside of the air space, is, for example, formed by a shield made of metal material, which undoubtedly offers greater rigidity relative to the reflecting and/or insulating material and greater resistance to scrapes and slight impacts.

Advantageously, according to a preferred embodiment of the invention, spacer elements are present between the front part of the air space interfacing with the outside environment and the back part of the air space closing the compartment. These elements have a primary function of preventing an impact against the outside front part of the air space from causing it to collapse internally.

According to their shape and dimensions, the spacer elements can also have an air conveying function, in practice delimiting one or more ventilation channels, for example as in the case of spacer elements extending continuously (for example continuous ribs, preferably parallel to one another) or prevalently continuously, or delimiting ventilation areas, in the case of spacer elements that are not elongated in shape and distribution in the air space, for example, in points or in an array.

Conveniently, in a preferred embodiment, the spacer elements extend in height substantially for the whole of the depth of the air space. Depth is intended as the distance between the two main inner faces of the air space, i.e. the one closing the housing compartment and the one interfacing with the outside environment.

In this case, a reflecting and/or insulating film or panel of soft type or with deformability of viscoelastic type or the like, is arranged between the spacer elements and the front part of the air space, to enable “absorb” any local deformation of the outer part caused by slight accidental impacts. This panel or film is able to reduce any sound waves coming from the device using a housing according to the invention.

It is understood that in other embodiments, the spacer elements can be of smaller dimensions, or with a height smaller than the depth of the air space.

According to a particularly advantageous embodiment of the invention, the ventilated air space has a substantially vertical extension for air inflow-outflow, i.e. the ventilation openings are arranged on a vertical directrix, i.e. from the bottom upwards, so as to promote the “chimney effect” of ventilation. It is understood that other orientations of the direction of ventilation are possible, for example orientation with horizontal or inclined directions.

Conveniently, according to another embodiment of the invention, the housing comprises a box-shaped container in which the compartment of the electronic components is defined. In particular, the cover extends beyond the edge of the box-shaped container, in practice defining at least two parts extending beyond the edge, preferably opposed relative to a central position of the compartment, i.e. outside a seal area that surrounds the compartment and defined between cover and box-shaped container, on which the ventilation openings of the air space are produced. Preferably, these openings are defined on the back face of the cover. In this way the openings are produced on surfaces prevalently “in the shade” relative to solar radiation, hence allowing the inflow of cooler air and consequently a more effective ventilating effect.

It is understood that the shape of the compartment can vary greatly, according to requirements, for example it can be square or rectangular, circular, polygonal or even amorphous in shape. In the case of square or rectangular shape, the central position of the compartment is defined as the intersection of the diagonals, while the central position of a circular compartment is given by the center of the circle that defines it.

In the preferred embodiment of the invention, the cover of the housing comprises a closing body of the compartment and a shield superimposed on and fixed to the body to define the ventilating air space. This configuration allows more flexible production and assembly, as it is also possible to choose the combinations of materials most suitable for the type of device on which the cover is to be used and for the site in which it is to be installed. Moreover, it facilitates maintenance and cleaning of the cover.

It is understood that in other embodiments the cover can be formed by a monolithic body, i.e. the closing body and the shield can be formed in one piece.

Conveniently, according to a preferred embodiment, the closing body is made of a die-cast metal material, such as an aluminum alloy (for example aluminum alloy EN AC 46100), while the shield is made, for example, of stainless steel (for example AIS1430).

Advantageously, the spacer elements can be formed in one piece with the closing body.

In the embodiment with closing body and shield, the heat reflecting barrier and/or insulating means (film or panel) are arranged on the inner face of the shield, between this and the spacer elements (preferably in contact with these).

If it is necessary to able to see inside the housing, for example to read a display for management of the electronic equipment contained in the compartment, a through pocket can advantageously be present on the cover. Optionally, this pocket can be closed by one or more elements, at least partly transparent or, in any case, suitable to allow viewing therethrough.

According to another aspect, the invention relates to a device for converting electrical current from direct to alternating in photovoltaic systems, comprising a housing according to one or more of the embodiments described above, optionally combined with one another according to one or more combinations, in which an inverter is contained. Although it is particularly suitable and effective in photovoltaic systems, it is understood that a device of this type can also be used in systems for producing electrical energy of different type, i.e. wherever there is the need to convert direct electrical current into alternating electrical current.

Conveniently, the housing of said device has a front part defined by the front cover and a back part for fixing to a supporting structure. A heat dissipation module is present on the back part, in thermal contact with the inverter (for example provided with dissipating fins). In this way, the heat dissipation part is placed “in the shade” by the housing body, while exposure to the sun takes place prevalently on the ventilated cover. The quantity of heat reaching the inside of the device or the dissipation module is thus greatly reduced relative to prior art devices, to the advantage of the overall efficiency of the device.

In a preferred embodiment, the heat dissipation module is formed in one piece with the box-shaped container that contains the inverter and it preferably has, on the rear face thereof, a dissipation channel recessed toward the inside of the container. With the device affixed to a wall, the dissipation module rests against or is positioned very close to this wall, and the dissipation channel, preferably oriented from the bottom upwards, is thus closed on its longitudinal side, in practice defining a ventilation duct open prevalently only on the upper and lower ends of the module.

### BRIEF DESCRIPTION OF THE DRAWINGS

Further features and advantages of the invention will be more apparent from the description of a preferred, but not exclusive, embodiment thereof, illustrated by way of non-limiting example in the appended drawings, wherein:

FIG. 1 represents a perspective front view of a device for converting electrical current from direct to alternating with housing according to the invention;

FIG. 2 represents a rear view of the device of FIG. 1;

FIG. 3 represents a bottom orthogonal view of the device of FIG. 1;

FIG. 4 represents a top view of the device of FIG. 1, sectioned according to the line IV-IV of FIG. 5.

FIG. 5 represents a side view of the device of FIG. 1, sectioned according to the line V-V of FIG. 4;

FIGS. 5a and 5b represent two enlargements of FIG. 5 relating to the upper and lower areas of the device;

FIG. 6 represents a rear view of the cover of the device of the previous figures;

FIG. 7 is an exploded axonometric view of the cover of FIG. 6;

FIG. 8 is a side view of the cover of the device according to the previous figures, sectioned according to the line IIX-IIX of FIG. 6;

FIGS. 9 and 10 represent two graphs illustrating the thermal improvements linked to the invention.

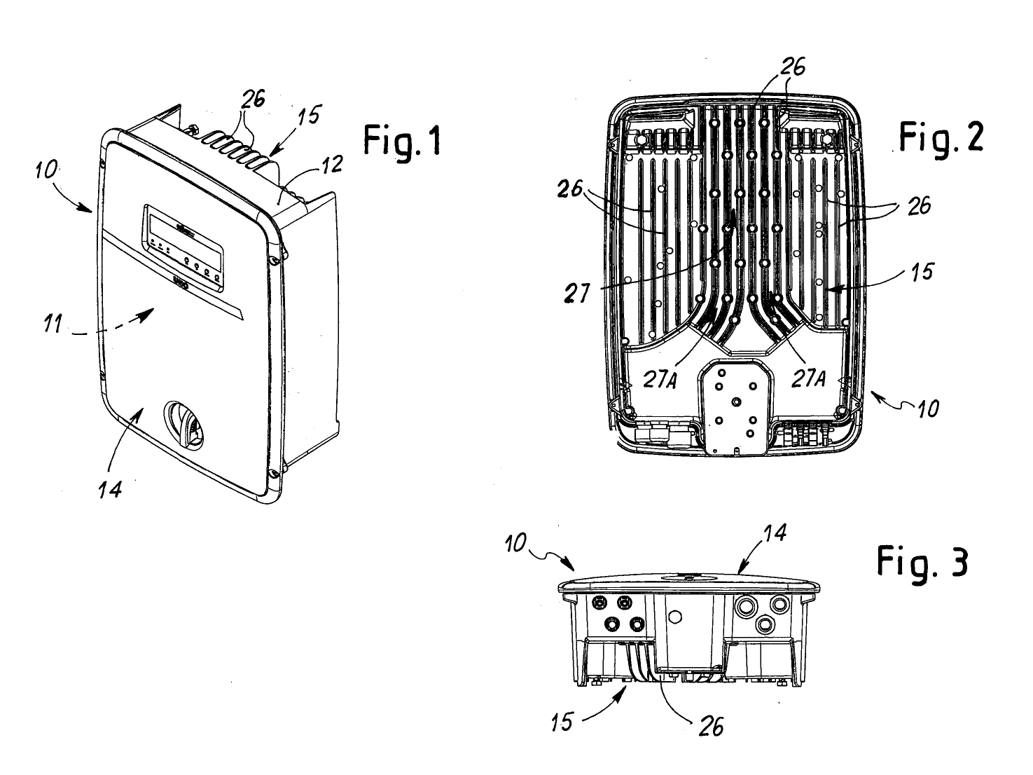

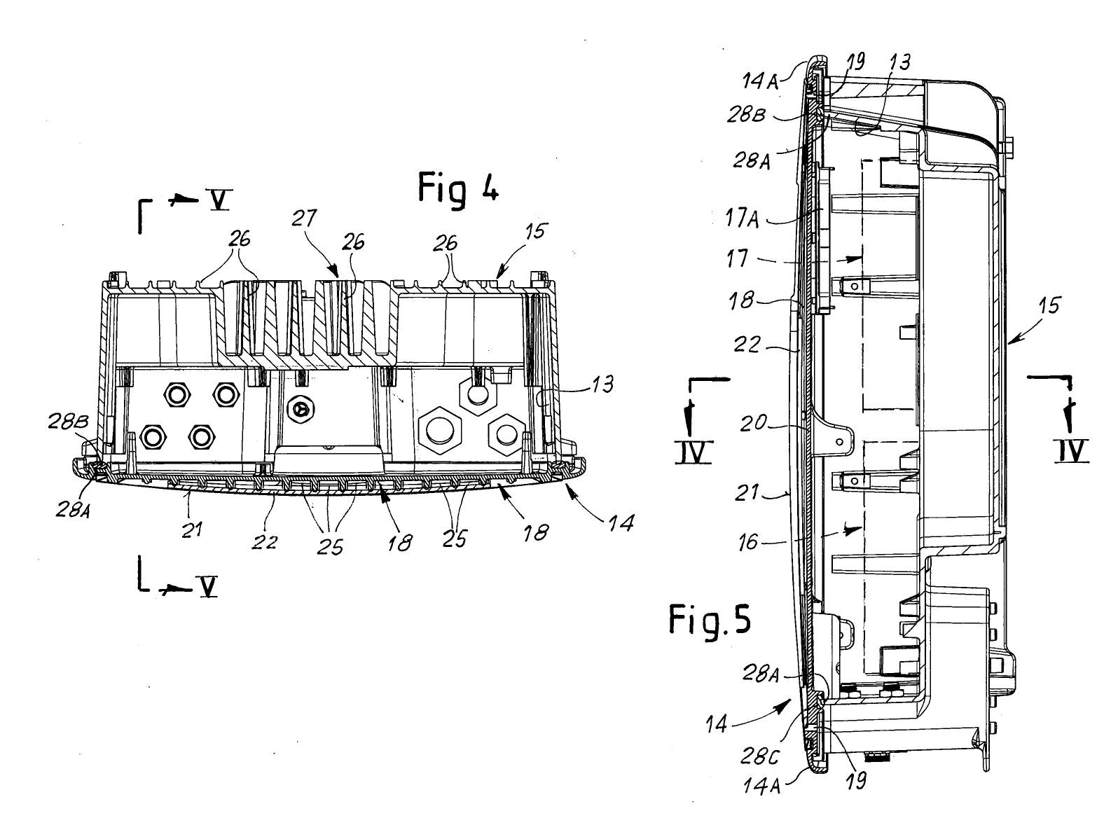

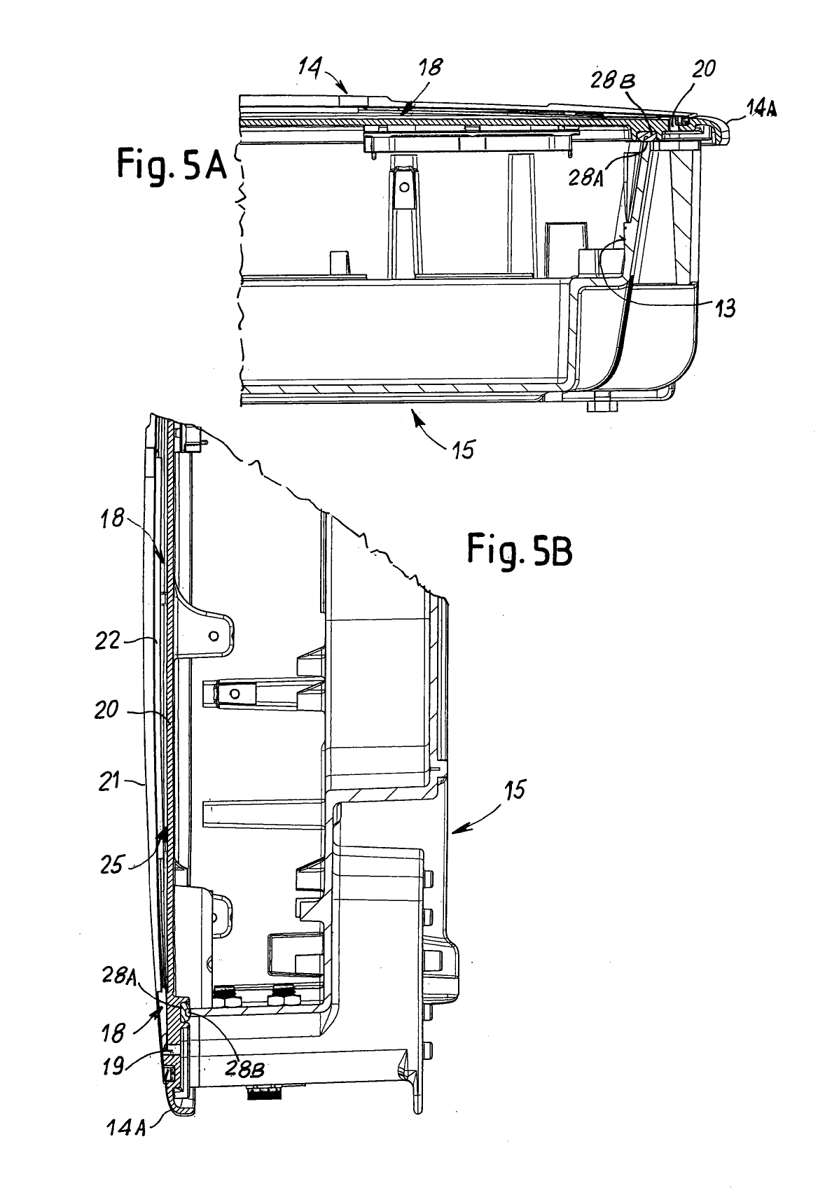

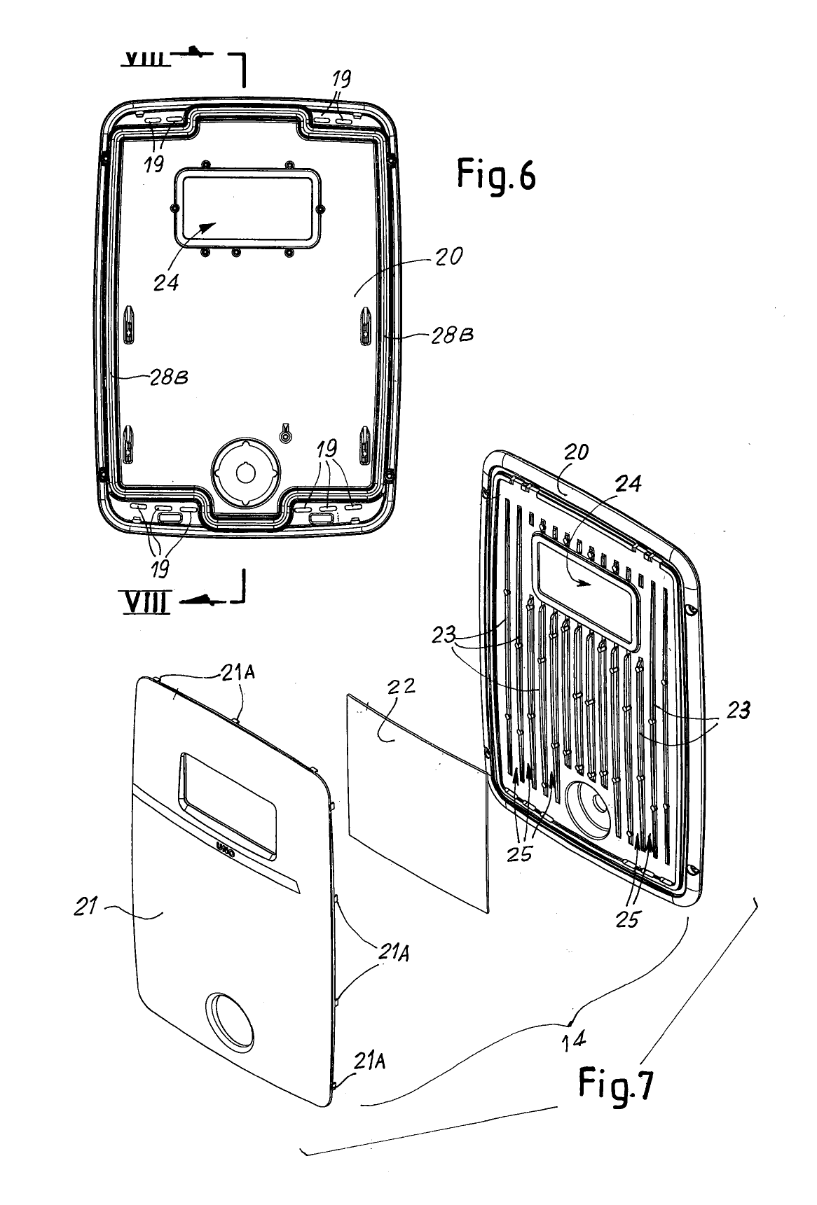

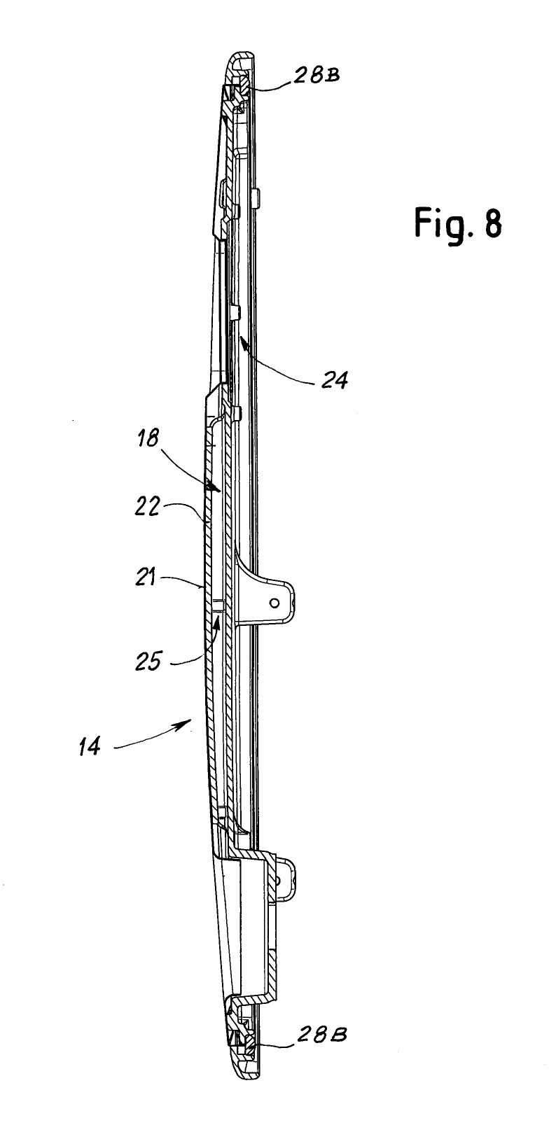

### DETAILED DESCRIPTION OF AN EMBODIMENT OF THE INVENTION

With reference to the aforesaid figures, a device for converting electrical current from direct to alternating arranged in a system for producing electrical energy of photovoltaic type is indicated as a whole with the reference numeral 10.

This device comprises a housing 11 defined by a box-shaped container 12 in which a compartment 13 is produced and by a cover 14 for closing the compartment 13.

A heat dissipation module 15, exposed to the outside environment, and better described below, is present on the back part of the housing 11, with the purpose of fastening to a supporting structure (not shown in the figures), such as a wall, a trellis framework or the like. The front part of the housing is substantially defined by the cover 14.

An inverter 16 (schematized by a dashed line) for converting the electrical current from direct to alternating is arranged inside the compartment 13, preferably in thermal contact with the heat dissipation module 15. Other electronic components, schematized by a dashed line and indicated with 17, serving the inverter 16, are also arranged inside the compartment 13. It must be noted that the inverter 16 and the electronic components 17 are indicated purely by way of example, and their shape and position can differ from those schematized by the dashed lines.

As can be seen in the figures, in this embodiment the cover 14 extends beyond the edge of the box-shaped container 12, in particular both from the top and from the bottom of the housing 11, with peripheral portions 14A extending beyond the edge.

According to the invention, an air space 18, provided with openings 19 toward the outside environment to allow ventilation of this air space, is defined on the cover 14.

More in particular, in this embodiment the cover 14 is formed by a closing body 20 of the compartment 13, for example flat and substantially quadrangular in shape, made of a die-cast metal material, such as aluminum alloy, and by a thin shield 21, preferably made of a metal material, such as stainless steel, superimposed on and fixed to the body 20 to define the air space 18. In practice, the front part of the air space acting as interface with the outside environment is formed by the shield 21, while the back part of the air space is formed by the closing body 20.

As is visible in the figures, in this example the shield 21 is convex, i.e. has a greater distance from the closing body 20 in the central area relative to the peripheral areas. Fixing of the shield to the closing body 20 is obtained reversibly, for example using tabs 21A (see FIG. 7) produced on the perimeter of the shield and suitable to be inserted in an interlocking manner into corresponding seats defined on the cover (these latter are not indicated explicitly in the figures).

The cover 14 preferably comprises a thermal radiation barrier, preferably a film 22 (or thin panel) made of a heat reflecting material, such as an expanded polymer material, for example a material based on low density polyethylene foam, such as the material known with the trade name Plastazote LD24 FR, arranged in contact with the inner face of the shield 21. Preferably, this film or panel 22 also forms insulating means and therefore has a material with heat insulating properties. Preferably, the dimensions of the film or panel 22 are smaller than the air space 18 or, more in general, smaller than the shield 21. In fact, the film or panel 22 extends only on the central part of the cover, i.e. is smaller in width and length (intended as measurements of the sides of the almost rectangular extension of the cover, i.e. vertical and horizontal measurements with the housing positioned in use) than the shield 21.

Conveniently, in this example the cover also has spacer elements 23 arranged between the closing body 20 and the shield 21, which have a first function of preventing excessive or permanent deformation of the shield in the case of accidental impacts. More in particular, in the preferred embodiment these spacer elements 23 are formed by longitudinal ribs that extend in height for the whole of the depth of the air space, i.e. in this embodiment extending from the closing body 20 to the heat insulating film 22. In this example the ribs 23 are parallel with one another and facing in vertical direction. Preferably, they are produced in one piece with the closing body 20.

In this embodiment, a through pocket 24 is produced in the center of the cover 14, counter-shaped to the shape of a display 17A associated with the electronic components 17 present in the compartment 13; the pocket thus allows viewing of this display. The pocket interrupts the continuity of the ribs 23 closest to the vertical center line plane of the cover.

The ribs 23 extend in substantially vertical direction between a lower area and an upper area of the closing body that correspond, in practice, to the peripheral portions 14A extending beyond the edge of the cover relative to the box-shaped container. On these lower and upper areas, i.e. on opposite sides of said air space relative to a substantially central position of the cover, through holes are produced, which correspond with the ventilation openings 19 of the air space toward the outside. These ventilation holes or openings 19 are thus defined on the back face of the cover 14 facing the box-shaped container and which in any case remains outside as it extends beyond the edge thereof.

It must be noted how the box-shaped container 12 has a seal area 28A surrounding the compartment 13 and suitable to abut, with seal, against a further seal area 28B defined on the cover 14 and consisting of a gasket. Preferably, the ventilation openings 19 of the air space 18 are defined on the part of the cover outside the compartment relative to said seal areas.

It must be noted how the ribs 23 delimit therebetween ventilation channels 25 that convey air between the lower and upper areas of the air space. In the example described, the channels 25 extend continuously between the two areas only in relation to the outermost ribs 23, the central ribs being interrupted by the through pocket 24.

The cover 14 for access to the compartment 13 of the device 10 being described is therefore a ventilating cover, i.e. capable of conveying a flow of air inside it (in this example from the bottom upwards, or vice versa) that reduces the quantity of heat transmittable from the front shield of the cover toward the compartment of the housing, heat resulting mainly from the solar radiation that strikes the shield.

As mentioned above, a heat dissipation module 15 is present on the back part of the housing 11. This module is, for example, produced in one piece with the box-shaped container, for example made of a die-cast metal material.

The module 15 has heat dissipation fins 26 extending outward from the box-shaped container. In particular, the module 15 also has a further channel 27 in the form of recess on the back part of the box-shaped container, extending from the bottom upwards and allowing air to be conveyed. In the case in which the box-shaped container is positioned against a wall, the further channel in practice forms a conveying duct toward the outside environment only open at the bottom and at the top of the container. On the bottom part, this channel/duct is split into two portions 27A.

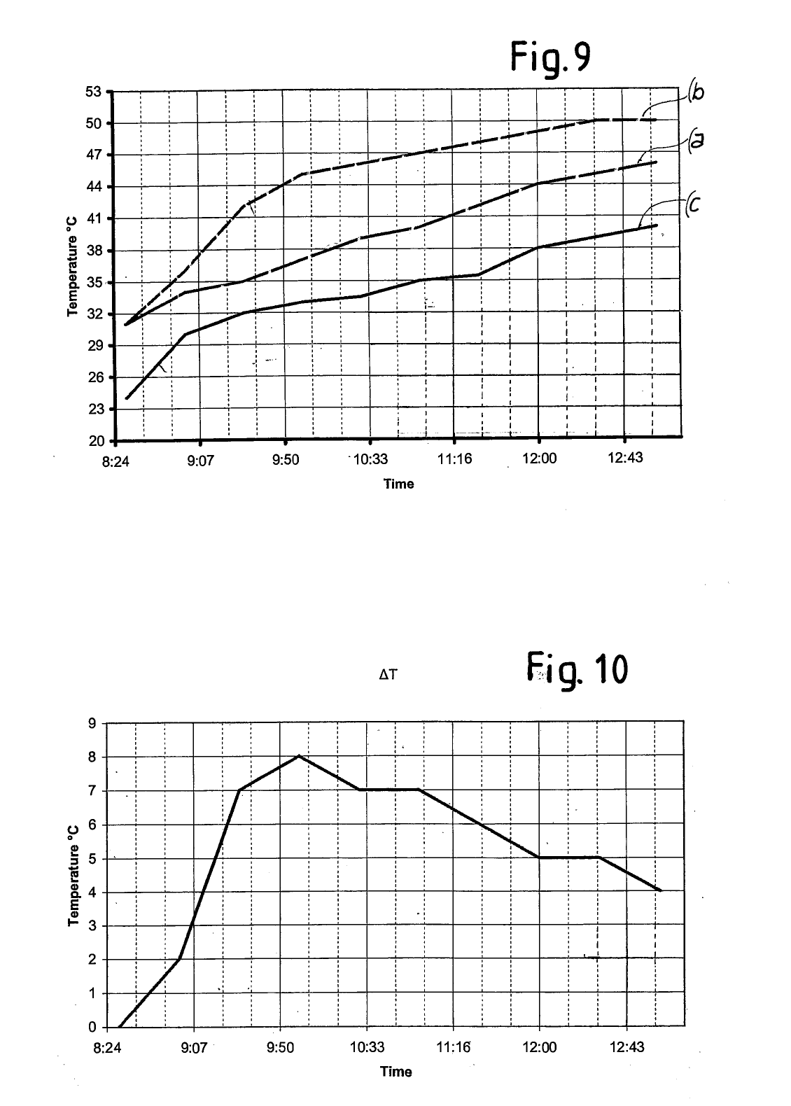

FIGS. 9 and 10 represent two graphs illustrating the beneficial effect obtained with a cover 14 such as the one described. In particular, FIG. 9 shows the trend in time (hours of the day) of the temperature measured inside the inverter housing, respectively (a) for a device with cover as described and (b) for a device with conventional cover, i.e. without air spaces and radiation barrier; the same graph also shows the trend of the ambient temperature (c). FIG. 10 shows the time differential of the temperature measured inside the housing of the inverter in the cases (a) and (b) of FIG. 9. It is understood that the above illustration only represents possible non-limiting embodiments of the invention, which can vary in forms and arrangements without departing from the scope of the concept underlying the invention. Any reference numerals in the appended claims are provided purely to facilitate reading thereof in the light of the description above and of the accompanying drawings, and do not in any way limit the scope of protection of the claims.

1-25. (canceled)

26. A housing for electronic power components, comprising:
a compartment defined inside the housing and configured to contain a plurality of electronic power components inside the housing;
a front cover removably connected to the compartment and configured to close the compartment; and
wherein the front cover has an inner part facing the compartment, a front part facing opposite the compartment, and an air space formed in the cover between the front part and the inner part.

27. The housing according to claim 26, wherein the cover comprises a thermal radiation barrier.

28. The housing according to claim 27, wherein the thermal radiation barrier comprises one of a heat reflecting film or a heat reflecting panel.

29. The housing according to claim 27, wherein the thermal radiation barrier is arranged in the air space.

30. The housing according to claim 28, wherein the thermal radiation barrier is smaller in at least one of a barrier width and a barrier height compared to a width and a height of the air space.

31. The housing according to claim 26, further comprising ventilation openings configured to ventilate the air space outside the housing.

32. The housing according to claim 26, further comprising an insulation structure associated with the front part of the air space interfacing with the outside environment.

33. The housing according to claim 32, wherein the insulation structure comprises heat insulating material formed as one of a film or a panel proximate to the inner face of the front part interfacing with the outside environment.

34. The housing according to claim 26, further comprising a plurality of spacer elements defined between the front part of the air space interfacing with the outside environment and the part of the air space closing the compartment.

35. The housing according to claim 34, wherein at least some of the plurality of spacer elements define ventilation channels.

36. The housing according to claim 35, wherein the spacer elements comprise continuous ribs.

37. The housing according to claim 36, wherein the spacer elements extend in height substantially for the whole of a depth of the air space.

38. The housing according to claim 31, wherein the ventilation openings are defined on the back face of the cover.

39. The housing according to claim 38, comprising a box-shaped container in which the compartment is defined, the container having a first seal area surrounding the compartment and configured to abut and seal a second seal area defined on the cover, the ventilation openings of the air space being defined on the part of the cover outside the compartment relative to the first and second seal areas.

40. The housing according to claim 39, wherein the ventilation openings are defined on opposite sides of the air space relative to a substantially central position of the cover.

41. The housing according to claim 40, wherein the ventilation openings are defined respectively on upper and lower portions of the cover with reference to a normal arrangement of the housing during its use, to further define ventilation chimneys with the channels.

42. The housing according to claim 26, wherein the cover comprises a closing body of the compartment and a shield superimposed on and fixed to the body to define the air space.

43. The housing according to claim 42, wherein the spacer elements are formed in one piece with the closing body.

44. The housing according to claim 43, wherein the thermal radiation barrier is arranged between the spacer elements and the shield, preferably in contact with the shield.

45. The housing according to claim 26, wherein the cover comprises a through pocket configured to allow reading of a display associated with electronic components arranged in the housing.

46. The housing according claim 26, further comprising a back part opposite the cover and a heat dissipation module positioned on the back part.

47. The housing according to claim 46, further comprising a box-shaped container in which the compartment is defined and closed by the cover, the heat dissipation module being formed in one piece with the back part of the box-shaped container.

48. The housing according to claim 46 or 47, wherein the heat dissipation module comprises dissipating fins.

49. A power converting device comprising:
a compartment;
a front cover removably connected to the compartment and configured to close the compartment;
wherein the front cover has an inner part facing the compartment, a front part facing opposite the compartment, and an air space formed in the cover between the front part and the inner part; and
an inverter contained inside the compartment.

50. The device according to claim 49, further comprising:
a back part opposite the cover;
a heat dissipation module positioned on the back part; and
wherein the inverter is in thermal contact with the heat dissipation module.
